(19) United States
(12) Patent Application Publication
(10) Pub. No.: US 2023/0146754 A1
(43) Pub. Date: May 11, 2023

(54) DISPLAY DEVICE

(71) Applicant: Japan Display Inc., Tokyo (JP)

(72) Inventor: Tomohiko NAGANUMA, Tokyo (JP)

(73) Assignee: Japan Display Inc., Tokyo (JP)

(21) Appl. No.: 17/978,975

(22) Filed: Nov. 2, 2022

(30) Foreign Application Priority Data
Nov. 8, 2021 (JP) 2021-181734

(51) Int. Cl. H10K 59/80; H10K 59/35

(52) U.S. Cl. CPC H10K 59/80522; H10K 59/352; H10K 59/12

(57) ABSTRACT

According to one embodiment, a display device includes a pixel electrode provided in each of a plurality of pixels, a bank provided between the adjacent pixel electrodes, an organic EL layer provided on the pixel electrode and provided in an opening of the bank, a common electrode provided over the first to third pixels, and an auxiliary electrode provided in at least one of the first to third pixels so as to overlap the common electrode and the organic EL layer.

### CROSS-REFERENCE TO RELATED APPLICATIONS

This application is based upon and claims the benefit of priority from Japanese Patent Application No. 2021-181734, filed Nov. 8, 2021, the entire contents of which are incorporated herein by reference.

### FIELD

Embodiments described herein relate generally to a display device.

### BACKGROUND

In recent years, organic electroluminescent (EL) display devices using the electroluminescence of an organic material have been drawing attention. Organic EL display devices have been applied to a direct-view-type display such as a monitor and a small display comprising fine pixels of several microns.

### BRIEF DESCRIPTION OF THE DRAWINGS

FIG. 1 is an entire perspective view of a display device according to embodiment 1.

FIG. 2 is a partial enlarged view of the display device.

FIG. 3 is a cross-sectional view of the display device along the line A1-A2 shown in FIG. 2.

FIG. 4 is a cross-sectional view in which part of a display device is enlarged according to a comparative example.

FIG. 5 is a cross-sectional view in which part of the display device is enlarged according to embodiment 1.

FIG. 6 is a plan view showing an example of the general configuration of the display device according to embodiment 1.

FIG. 7 is a cross-sectional view showing an example of the general configuration of a display device according to embodiment 2.

FIG. 8 is a plan view showing an example of the general configuration of the display device according to embodiment 2.

FIG. 9 is a plan view showing a configuration example of the display device according to embodiment 2.

FIG. 10 is a plan view showing a configuration example of the display device according to embodiment 2.

FIG. 11 is a plan view showing a configuration example of the display device according to embodiment 2.

### DETAILED DESCRIPTION

In general, according to one embodiment, a display device comprises a plurality of pixels comprising a first pixel which emits red light, a second pixel which emits green light and a third pixel which emits blue light; a pixel electrode provided in each of the pixels; a bank provided between the adjacent pixel electrodes; an organic EL layer provided on the pixel electrode and provided in an opening of the bank; a common electrode provided over the first to third pixels; and an auxiliary electrode provided in at least one of the first to third pixels so as to overlap the common electrode and the organic EL layer.

According to another embodiment, a display device comprises a plurality of pixels comprising a first pixel which emits red light, a second pixel which emits green light and a third pixel which emits blue light; a pixel electrode provided in each of the pixels; a bank provided between the adjacent pixel electrodes; an organic EL layer provided on the pixel electrode and provided in an opening of the bank; a common electrode provided in each of the pixels; and an auxiliary electrode having a line shape and overlapping part of the common electrode.

An embodiment of the present invention provides a display device which can obtain a sufficient microcavity effect and which has improved luminance.

An embodiment of the present invention can provide a display device which prevents generation of leak current and has improved reliability.

Embodiments will be described hereinafter with reference to the accompanying drawings. The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, the same elements as those described in connection with preceding drawings are denoted by like reference numbers, and detailed description thereof is omitted unless necessary.

This specification explains the details of a display device according to each embodiment with reference to the accompanying drawings.

In the embodiments, a first direction X, a second direction Y and a third direction Z are perpendicular to one another. However, they may intersect one another at an angle other than 90 degrees. The third direction Z is defined as an upward direction or a direction toward an upper side. The opposite direction of the third direction Z is defined as a downward direction or a direction toward a lower side. The first direction X, the second direction Y and the third direction Z are also referred to as an X direction, a Y direction and a Z direction, respectively.

When this specification uses the phrases “a second member above a first member” and “a second member on the lower side relative to a first member”, the second member may be in contact with the first member, or may be spaced apart from the first member. In the latter case, a third member may be interposed between the first member and the second member. When this specification uses the phases “a second member on a first member” and “a second member under a first member”, the second member is in contact with the first member.

It is assumed that an observation position for observing a display device is on the tip side of the arrow of the third direction Z. When the X-Y plane defined by the first direction X and the second direction Y is viewed at the observation position, the appearance is referred to as a plan view. When the section of the display device in the X-Z plane defined by the first direction X and the third direction Z or in the Y-Z plane defined by the second direction Y and the third direction Z is viewed, the appearance is referred to as a cross-sectional view.

### Embodiment 1

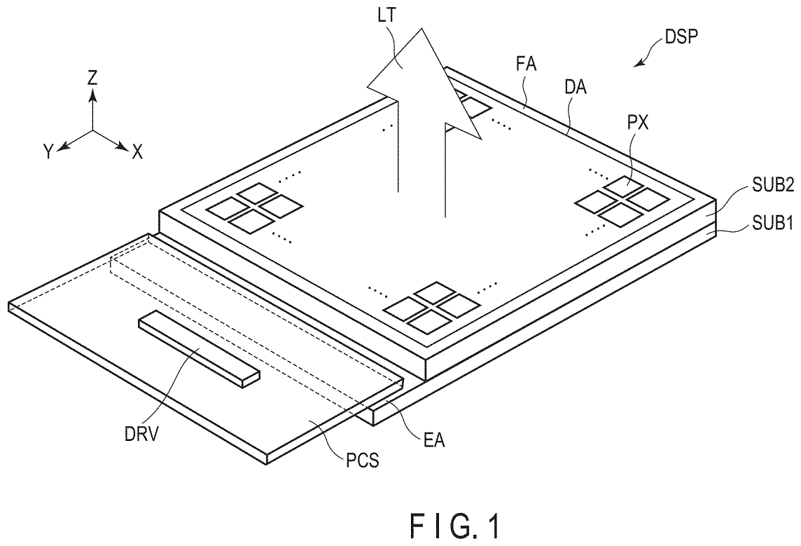

FIG. 1 is an entire perspective view of a display device according to embodiment 1. The display device DSP comprises, in a substrate SUB1, a display area DA and a peripheral area FA provided around the display area DA. The display device DSP comprises a plurality of pixels PX provided in the display area DA. Light LT passes through the display device DSP from the back side to the adverse side as well as passing through the display device DSP in the opposite direction.

A substrate SUB2 is provided as a sealing member on the top surface of the display area DA. The substrate SUB2 is fixed to the substrate SUB1 by a sealing material (not shown) surrounding the display area DA. The display area DA formed in the substrate SUB1 is sealed by the substrate SUB2 as a sealing member and the sealing material such that the display area DA is not exposed to air.

An area EA which is an end portion of the substrate SUB1 is provided outside the substrate SUB2. In the area EA, a circuit substrate PCS is provided. In the circuit substrate PCS, a driver DRV which outputs a video signal and a drive signal is provided. The signals from the driver DRV are input to the pixels PX of the display area DA via the circuit substrate PCS. Based on video signals and various control signals, the pixels PX emit light.

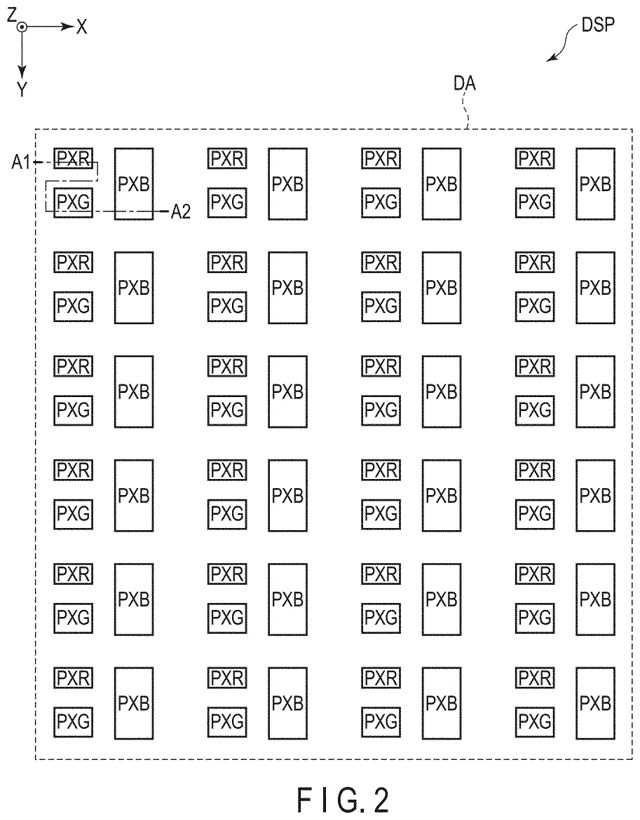

FIG. 2 is a partial enlarged view of the display device. As shown in FIG. 2, the pixels PX include pixels PXR which emit red light, pixels PXG which emit green light and pixels PXB which emit blue light. Pixels PXR, PXG and PXB may be called first, second and third pixels, respectively.

The size of each of pixels PXR, PXG and PXB is increased in this order. It should be noted that the size of pixel PXB is approximately twice the size of each of pixels PXR and PXG because pixel PXB which emits blue light has a luminance less than that of pixels PXR and PXG. It should be noted that pixel PXR and pixel PXG may have the same size. Alternatively, pixel PXG which emits green light and has a high luminance may be smaller than the other pixels PXR and PXB.

Pixel PXR is provided so as to be adjacent to pixel PXG in the first direction Y. Pixel PXR is provided so as to be adjacent to pixel PXB in the second direction Y.

Pixel PXG is provided so as to be adjacent to pixel PXB in the first direction X. Pixel PXG is provided so as to be adjacent to pixel PXR in the second direction.

Pixel PXB is provided so as to be adjacent to pixels PXR and PXG in the first direction X. A pixel PXB is provided so as to be adjacent to another pixel PXB in the second direction Y.

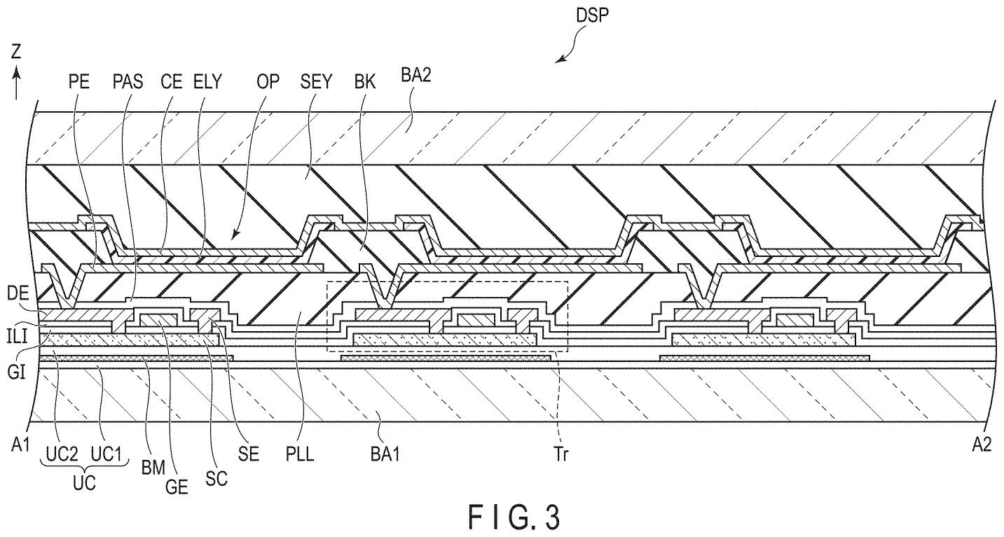

FIG. 3 is a cross-sectional view of the display device along the line A1-A2 shown in FIG. 2.

A base material BA1 may be a base material consisting of, for example, glass or a resinous material. For the resinous material, for example, acrylic, polyimide, polyethylene terephthalate and polyethylene naphthalate may be used. The resinous material may be formed by a single layer of any one of these components or by stacking a plurality of layers.

An insulating layer UC1 is provided on the base material BA1. For example, the insulating layer UC1 is formed by a single layer of a silicon oxide film or a silicon nitride film or by stacking the films.

A light-shielding layer BM may be provided on the insulating layer UC1 so as to overlap a transistor Tr. The light-shielding layer BM prevents the change in the transistor characteristics because of the incursion of light from the channel back surface of the transistor Tr, etc. When the light-shielding layer BM is formed by a conductive layer, a back gate effect can be caused to the transistor Tr by applying a predetermined potential.

An insulating layer UC2 is provided so as to cover the insulating layer UC1 and the light-shielding layer BM. For the insulating layer UC2, the same material as the insulating layer UC1 may be used. The insulating layer UC2 may be formed of a material different from that of the insulating layer UC1. For example, the insulating layer UC1 may be formed of silicon oxide, and the insulating layer UC2 may be formed of silicon nitride. The insulating layers UC1 and UC2 are collectively referred to as an insulating layer UC.

On the insulating layer UC, the transistor Tr is provided. The transistor Tr comprises a semiconductor layer SC, an insulating layer GI, a gate electrode GE (scanning line), an insulating layer ILI, a source electrode SE (signal line) and a drain electrode DE.

For the semiconductor layer SC, amorphous silicon, polysilicon or an oxide semiconductor is used.

For example, the insulating layer GI is provided by a single layer of silicon oxide or silicon nitride or by stacking them.

For the gate electrode GE, for example, molybdenum tungsten alloy (MoW) is used. The gate electrode GE may be integrally formed with a scanning line.

The insulating layer ILI is provided so as to cover the semiconductor layer SC and the gate electrode GE. For example, the insulating layer ILI is formed by a single layer of silicon oxide or silicon nitride or by stacking them.

The source electrode SE and the drain electrode DE are provided on the insulating layer ILI. The source electrode SE and the drain electrode DE are connected to the source area and drain area of the semiconductor layer SC, respectively, via the contact holes provided in the insulating layer ILI and the insulating layer GI. The source electrode SE may be integrally formed with a signal line.

An insulating layer PAS is provided so as to cover the source electrode SE, the drain electrode DE and the insulating layer ILI. An insulating layer PLL is provided so as to cover the insulating layer PAS.

The insulating layer PAS is formed of an inorganic insulating material. For example, the inorganic insulating material is prepared as a single layer of silicon oxide or silicon nitride or a stacked layer of these components. The insulating layer PLL is formed of an organic insulating material. The organic insulating material may be an organic material such as photosensitive acrylic or polyimide. By providing the insulating layer PLL, a step caused by the transistor Tr can be planarized.

On the insulating layer PLL, a pixel electrode PE is provided. The pixel electrode PE is connected to the drain electrode DE via a contact hole provided in the insulating layers PAS and PLL.

For example, the pixel electrode PE comprises a multilayer structure of three layers of indium zinc oxide (IZO), silver (Ag) and IZO.

A bank BK (a protrusion or a rib) is provided between adjacent pixel electrodes PE. For the bank BK, the same organic material as the insulating layer PLL is used. The bank BK is open so as to expose part of the pixel electrode PE. An end portion of an opening OP should preferably have a gentle taper shape. If an end portion of the opening OP is steep, a coverage defect is cased in an organic EL layer ELY which is formed later.

The organic EL layer ELY is provided between adjacent banks BK so as to overlap the pixel electrode PE. The organic EL layer ELY includes a hole-transport layer, a light emitting layer and an electron-transport layer.

A common electrode CE is provided so as to cover the organic EL layer ELY and the bank BK. The common electrode CE is the so-called solid film, and is provided over pixels PXR, PXG and PXB. The common electrode CE is prepared by forming a magnesium-silver alloy (MgAg) film as a thin film to the extent that the emitted light from the organic EL layer ELY passes though the film. In at least one of the pixels PX, for example, in pixel PXR, an auxiliary electrode is formed on the common electrode CE. The details of the auxiliary electrode are described later.

In the present embodiment, the pixel electrode PE is an anode, and the common electrode CE is a cathode. The light generated in the organic EL layer ELY is extracted to the upper side via the common electrode CE. In other words, the display device DSP comprises a top-emission structure.

An insulating layer SEY is provided so as to cover the common electrode CE. The insulating layer SEY comprises a function of preventing the incursion of liquid from the outside into the organic EL layer ELY. A material having a high gas barrier property is suitable for the insulating layer SEY. The insulating layer SEY may be, for example, an insulating layer in which an organic insulating layer is interposed between two inorganic insulating layers containing nitrogen. The material of the organic insulating layer may be acrylic resin, epoxy resin, polyimide resin, etc. The material of the inorganic insulating layers containing nitrogen may be, for example, silicon nitride or aluminum nitride.

A base material BA2 is provided on the insulating layer SEY. The base material BA2 is formed of the same material as the base material BA1. An inorganic insulating layer or organic insulating layer having translucency may be provided between the base material BA2 and the insulating layer SEY. The organic insulating layer may comprise a function of attaching the insulating layer SEY to the base material BA2.

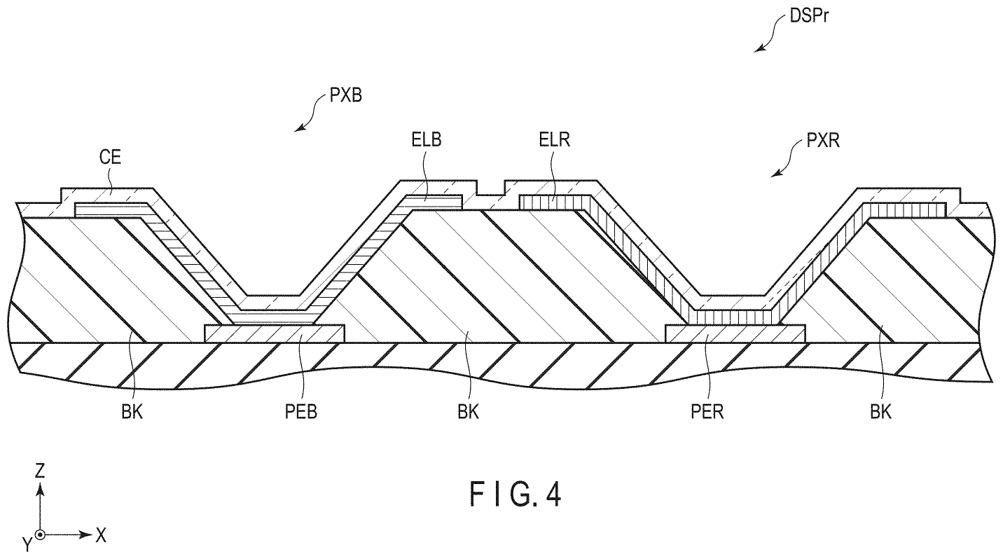

FIG. 4 is a cross-sectional view in which part of a display device is enlarged according to a comparative example. In the display device DSPr shown in FIG. 4, pixel PXB is adjacent to pixel PXR. Between adjacent banks BK, an organic EL layer corresponding to a pixel PX is provided. For example, organic EL layers ELB and ELR are provided as organic EL layers ELY in pixels PXB and PXR, respectively.

As described above, a common electrode CE is provided so as to cover the organic EL layers ELY and the banks BK. The common electrode CE is a conductive film which is integrally formed over a plurality of pixels PX.

In each pixel PX, light is emitted from the organic EL layer ELY to the upper side or the lower side. The light emitted to the upper side is extracted to the outside via the common electrode CE. The light emitted to the lower side is reflected on a pixel electrode PE. For example, when the pixel electrode PE comprises a multilayer structure of three layers of IZO, silver (Ag) and IZO, the light is reflected on the silver layer. The reflected light repeats reflection between the pixel electrode PE and the common electrode CE. In this way, of the light emitted from the organic EL layer ELY, only the light in which the length of the optical path is equal to the wavelength or is an integral multiple of the wavelength is amplified. As a result, light having a high peak intensity and a narrow spectrum can be extracted, thereby expanding the color gamut of the display device DSP (microcavity effect).

The microcavity effect depends on the length of the optical path and the wavelength of light. The length of the optical path depends on the sum of the film thicknesses of the pixel electrode PE, the organic EL layer ELY and the common electrode CE. In the display device DSPr, the film thickness of each of the pixel electrode PE, the organic EL layer ELY and the common electrode CE is constant without depending on the pixel PX. In other words, in pixel PXR which emits red light, pixel PXG which emits green light and pixel PXG which emits blue light, the length of the optical path is the same.

However, the light emitted from pixels PXR, PXG and PXB has different wavelengths. The display device DSPr of the comparative example in which the length of the optical path is the same in the pixels although the wavelength differs depending on the pixel cannot sufficiently exert a microcavity effect of intensifying the light having a wavelength coincident with the length of the optical path by the resonance of light and weakening the light having the other wavelengths.

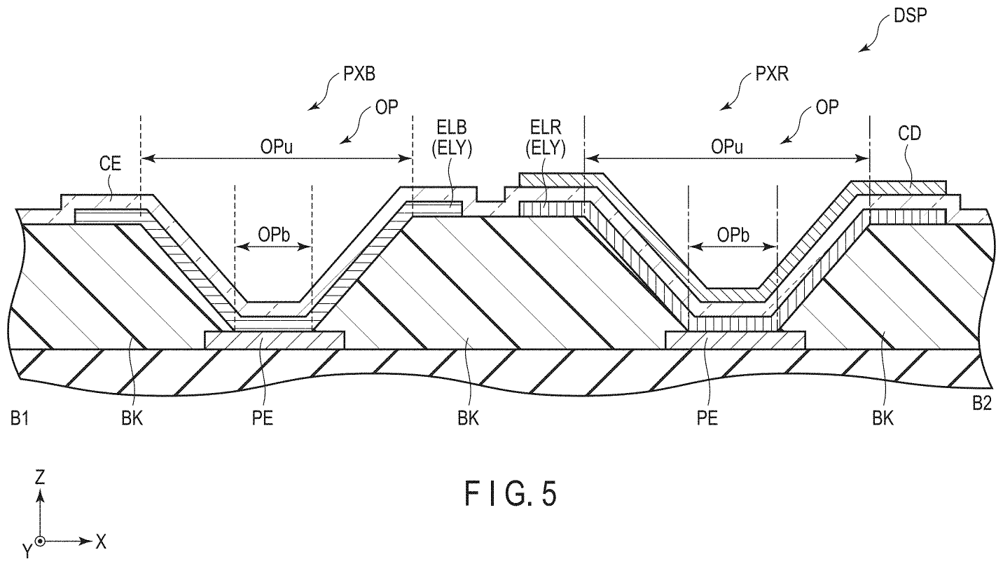

FIG. 5 is a cross-sectional view in which part of the display device is enlarged according to the present embodiment. In the display device DSP of the present embodiment, the length of the optical path is changed depending on the wavelength of the light emitted from each pixel PX. In other words, the thickness of a layer regarding light emission is changed for each of pixels PXR, PXG and PXB. By this configuration, a sufficient microcavity effect can be obtained. In this way, the efficiency of extraction of light is improved. Thus, a display device in which the luminance is improved can be obtained.

For example, pixel PXB of the display device DSP is the same as pixel PXB of the display device DSPr of the comparative example. Pixel PXR of the display device DSP is different from pixel PXR shown in FIG. 4 in respect that an auxiliary electrode CD is provided together with the common electrode CE.

In pixel PXR, the auxiliary electrode CD is provided on the common electrode CE. The sum total of the film thicknesses of the auxiliary electrode CD and the common electrode CE may be determined based on the wavelength of the light emitted from the organic EL layer ELR. The auxiliary electrode CD and the common electrode CE constitute a cathode.

For example, the auxiliary electrode CD may be provided in each pixel PX by coating or by using a photolithographic technique after the formation by vapor deposition. For example, when the auxiliary electrode CD is provided by coating, the film thickness can be easily controlled. Thus, coating is preferred. The material of the auxiliary electrode CE may be the same as the common electrode CE or different from that of the common electrode CE. In FIG. 5, the auxiliary electrode CD is provided on the common electrode CE. However, the structure is not limited to this example. On the organic EL layer ELY (organic EL layer ELR), the auxiliary electrode CD may be provided, and further, the common electrode CE may be provided. In other words, the common electrode CE may be provided between the auxiliary electrode CD and the organic EL layer ELY. Alternatively, the auxiliary electrode CE may be provided between the common electrode CE and the organic EL layer.

In the example shown in FIG. 5, the cross-sectional structure of pixels PXR and PXG is explained. However, the structure is not limited to this example. The auxiliary electrode CD may be also provided for pixels PXB and PXG. When the auxiliary electrode CD is provided in, of pixels PXR, PXG and PXB, for example, pixels PXR and PXB, the film thickness of the auxiliary electrode CD may differ between pixel PXR and pixel PXB. More specifically, the film thickness of the auxiliary electrode CD provided in pixel PXR which emits light having a longer wavelength may be greater than that of the auxiliary electrode CD provided in pixel PXG which emits light having a shorter wavelength.

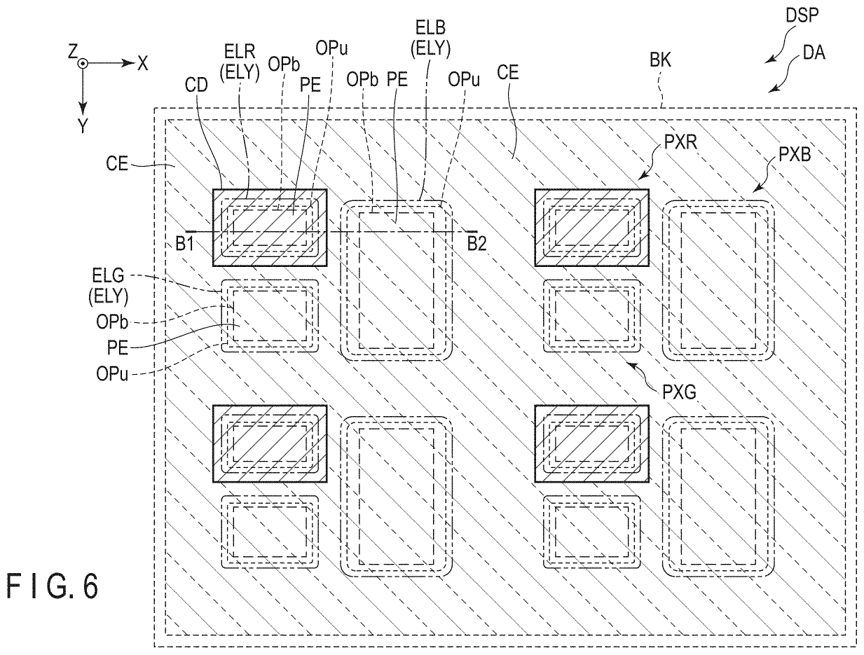

FIG. 6 is a plan view showing an example of the general configuration of the display device according to the present embodiment. The diagram showing the cross-sectional structure of the display device DSP along the line B1-B2 shown in FIG. 6 is FIG. 5. In the example shown in FIG. 6, the auxiliary electrode CD is provided in only pixel PXR. It should be noted that, as described above, the auxiliary electrode CD may be provided in pixel PXG or PXB, or both of them.

The opening OP is an opening provided in the bank BK. The pixel electrode PE is provided on the lower side so as to overlap the opening OP. The organic EL layer ELY (ELR, ELG, ELB) is provided on the upper side so as to overlap the opening OP. The common electrode CE is provided on the organic EL layers ELY over pixels PXR, PXG and PXB. The bottom portion of the opening OP is defined as OPb, and the upper portion is defined as OPu.

The auxiliary electrode CD is provided so as to overlap the opening OP, pixel PE and organic EL layer ELR (ELY) of pixel PXR, and the common electrode CE. As described above, the thickness of the auxiliary electrode CD may be determined based on the wavelength of the light emitted from the organic EL layer ELR such that a microcavity effect can be sufficiently obtained.

The present embodiment can provide a display device which can realize a sufficient microcavity effect. In this display device, the efficiency of extraction of light can be increased, and image light having a high luminance can be obtained.

### Embodiment 2

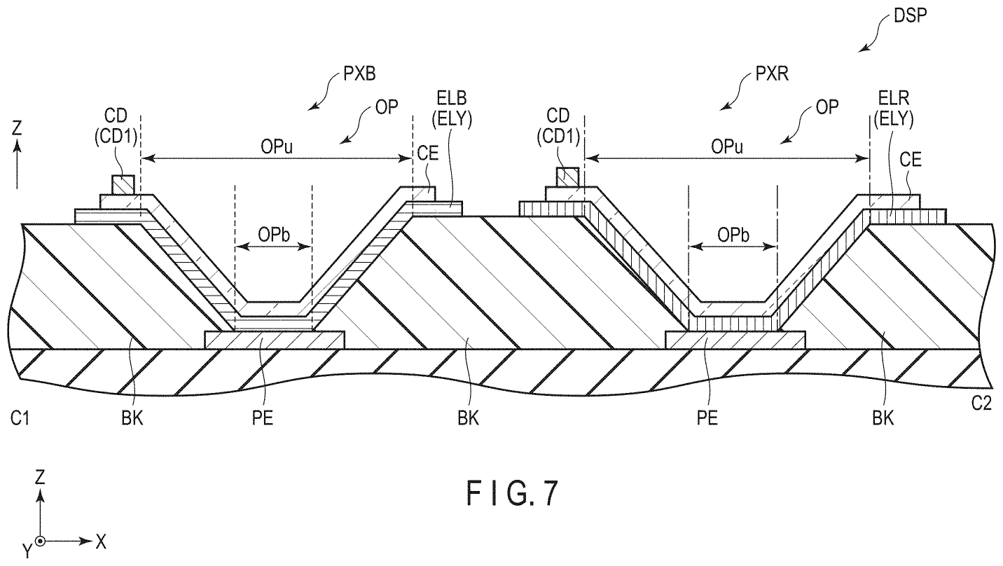

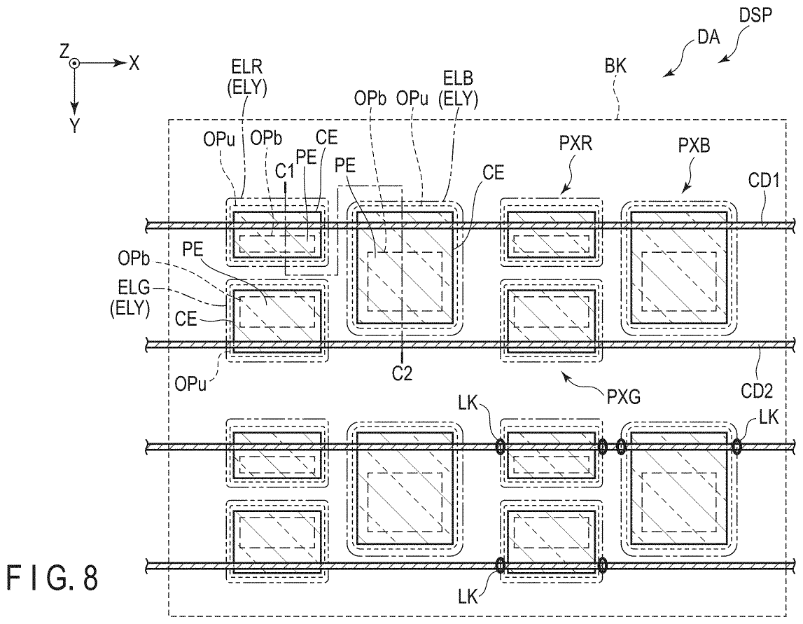

FIG. 7 is a cross-sectional view showing an example of the general configuration of a display device according to embodiment 2. The configuration example shown in FIG. 7 is different from the configuration example shown in FIG. 5 in respect that each of a common electrode and an auxiliary electrode is provided so as to overlap part of an organic EL layer. FIG. 8 is a plan view showing an example of the general configuration of the display device according to the present embodiment. The cross-sectional view of the display device along the line C1-C2 shown in FIG. 8 is FIG. 7.

In the display device DSP of the present embodiment, a common electrode CE is not provided over pixels PX, and is provided in each pixel PX, in other words, in each of pixels PXR, PXG and PXB. The common electrode CE is provided on an organic EL layer ELY. An end portion of the common electrode CE is located on the inner side compared to an end portion of the organic EL layer ELY. In a manner similar to that of the auxiliary electrode CD of the embodiment, the common electrode CE may be provided, for example, by coating or by using a photolithographic technique after the formation by vapor deposition.

The auxiliary electrode CD has a line shape and extends in the first direction X as seen in a plan view. The auxiliary electrode CD comprises auxiliary electrodes CD1 and CD2 parallel to each other. The auxiliary electrode CD1 is provided above the organic EL layer ELY (ELR, ELB) of each of pixels PXR and PXB across the intervening common electrode CE and overlaps part of the organic EL layer ELY. The auxiliary electrode CD2 is provided above the organic EL layer ELY (ELB, not shown) of pixel PXB across the intervening common electrode CE and overlaps part of the organic EL layer ELY.

Thus, the auxiliary electrodes CD1 overlap end portions of the common electrodes CE provided on the organic EL layers ELY of pixels PXR and PXB. The auxiliary electrode CD2 overlaps an end portion of the common electrode CE provided on the organic EL layer ELY of pixel PXG. The auxiliary electrode CD1 and the auxiliary electrode CD2 are also referred to as a first auxiliary electrode and a second auxiliary electrode, respectively.

It should be noted that, in the present embodiment, in a manner similar to that of embodiment 1, the common electrode CE may be provided between the auxiliary electrode CD and the organic EL layer ELY. The auxiliary electrode CE may be provided between the common electrode CE and the organic EL layer.

In FIG. 7, the thickness of the common electrode CE is less than that of the auxiliary electrode CD. When the common electrode CE is made thin, the light emitted from the organic EL layer ELY can effectively pass through the common electrode CE. The thickness of the common electrode CE should be, for example, greater than or equal to 10 nm and less than or equal to 20 nm.

The auxiliary electrode CD does not block the transmission of the light emitted from the organic EL layer ELY. Thus, the auxiliary electrode CD can be made thick. When the auxiliary electrode CD is made thick, the resistance can be sufficiently decreased.

The auxiliary electrode CD and the common electrode CE are formed so as to expose an end portion of the organic EL layer ELY. When an end portion of the organic EL layer ELY overlaps a cathode (the auxiliary electrode CD and the common electrode CE), leak current is generated by the characteristics (VI characteristics) between the voltage applied to the pixel PX and the flowing current. If this leak current is generated, a detrimental effect may be caused to the reliability of the display device DSP.

To prevent the generation of leak current, in the present embodiment, an end portion of the organic EL layer ELY does not overlap the common electrode CE or auxiliary electrode CD of the cathode. Alternatively, even if an end portion of the organic EL layer ELY overlaps the common electrode CE and the auxiliary electrode CD, the overlapping portion is made as small as possible.

In the example shown in FIG. 8, the length in which an end portion of the organic EL layer ELY overlaps the auxiliary electrode CD is only the length of the auxiliary electrode CD in the second direction Y. As the portion LK in which an end portion of the organic EL layer ELY overlaps the auxiliary electrode CD can be made small, even if leak current is generated, its effect can be suppressed.

In the present embodiment, carrier injection from the cathode into the organic EL layer ELY is uniform, thereby preventing the generation of leak current. In this way, a display device in which the reliability is improved can be obtained.

### Configuration Example 1

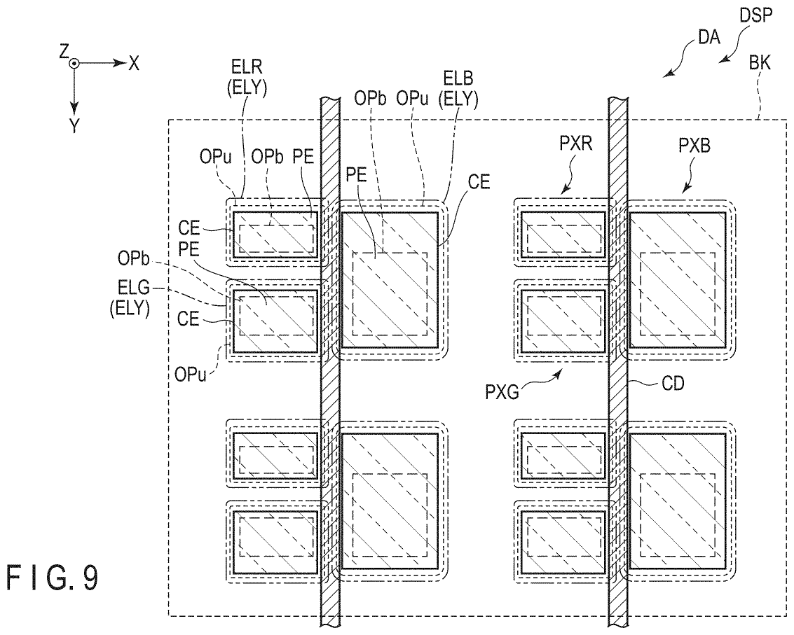

FIG. 9 is a plan view showing another configuration example of embodiment 2. The configuration example shown in FIG. 9 is different from the configuration example shown in FIG. 8 in respect that the auxiliary electrode extends in the second direction Y.

In the example shown in FIG. 9, the auxiliary electrode CD extending in the second direction Y overlaps end portions of the common electrodes CE and end portions of the organic EL layers ELY (ELR, ELG and ELB) provided in pixels PXR, PXG and PXB. In other words, the auxiliary electrode CD having a line shape overlaps end portions of the common electrodes CE provided on the organic EL layers ELY.

However, not all end portions of the common electrodes CE overlap the auxiliary electrode CD. The area of the end portions of the common electrodes CE overlapping the auxiliary electrode CD is less than that of the end portions which do not overlap the auxiliary electrode CD.

Similarly, not all end portions of the organic EL layers ELY overlap the auxiliary electrode CD. The area of the end portions of the organic EL layers ELY overlapping the auxiliary electrode CD is less than that of the end portions which do not overlap the auxiliary electrode CD.

Thus, in the example shown in FIG. 9, similarly, the generation of leak current can be prevented. Alternatively, even if leak current is generated, the current value can be made less.

In this configuration example, effects similar to those of embodiment 2 can be obtained.

### Configuration Example 2

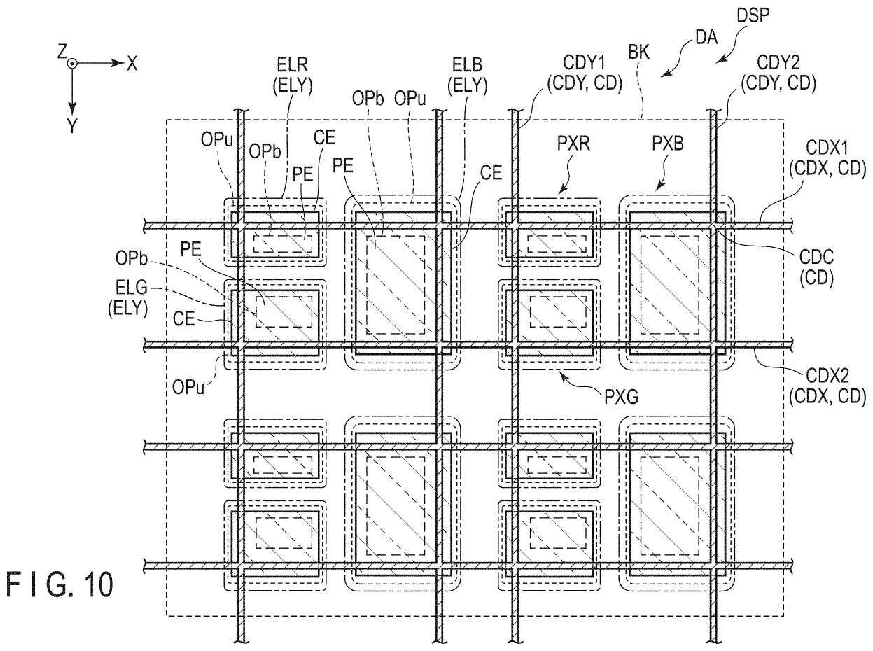

FIG. 10 is a plan view showing another configuration example of the display device according to embodiment 2. The configuration example shown in FIG. 10 is different from the configuration example shown in FIG. 8 in respect that the auxiliary electrode extends in both the first direction and the second direction Y.

The auxiliary electrode CD shown in FIG. 10 is provided in a grating shape. The auxiliary electrode CD comprises area CDX extending in the first direction X, area CDX extending in the second direction Y, and area CDC in which areas CDX and CDY intersect each other. Areas CDX, CDY and CDC are also referred to as first, second and third areas, respectively.

Areas CDX, CDY and CDC are provided in the outer edge portion of the area in which the organic EL layer ELY is provided. Area CDX further comprises areas CDX1 and CDX2. Area CDY further comprises areas CDY1 and CDY2.

Area CDX1 overlaps pixels PXR and PXB. Area CDX2 overlaps pixels PXG and PXB. Area CDY1 overlaps pixels PXR and PXG and does not overlap pixel PXB. Area CDY2 overlaps pixel PXB and does not overlap pixel PXR or PXG.

FIG. 10 shows that each pixel PX overlaps at least a single area CDX and a single area CDY. Pixel PXR overlaps area CDX1 and area CDY1. Pixel PXG overlaps areas CDX2 and CDY1. Pixel PXB overlaps areas CDX1, CDX2 and CDY2.

Neither area CDX nor area CDY overlaps the bottom portion OPb of the opening OP of the bank BK. In other words, neither area CDX nor area CDY overlaps the pixel electrode PE.

In a manner similar to that of the above descriptions, not all outer edge portions of the organic EL layers ELY overlap area CDX, CDY or CDC. The area of the outer edge portions of the organic EL layers ELY overlapping these areas is less than that of the outer edge portions which do not overlap the above areas. In the example shown in FIG. 10, similarly, the generation of leak current can be prevented. Alternatively, even if leak current is generated, the current value can be made less.

In this configuration example, effects similar to those of embodiment 2 can be obtained.

### Configuration Example 3

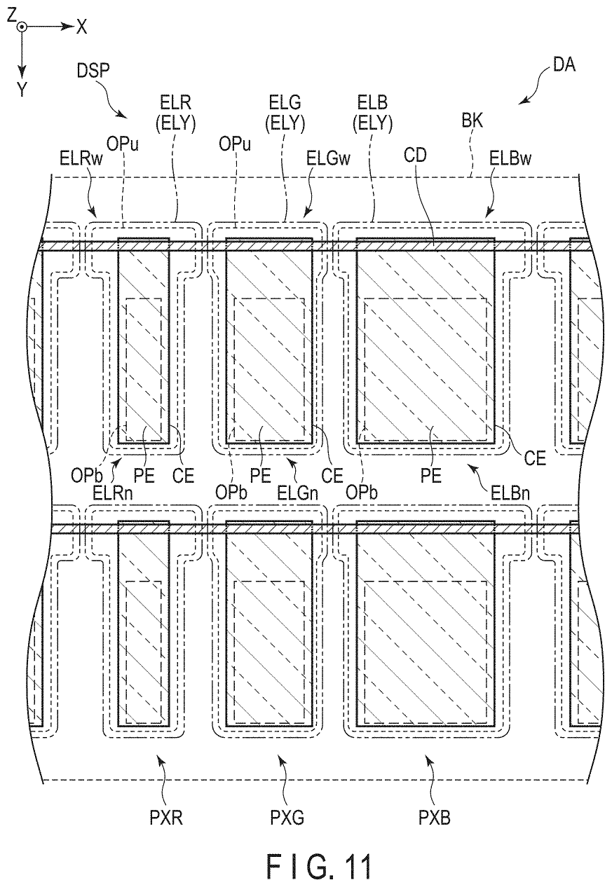

FIG. 11 is a plan view showing another configuration example of the display device according to embodiment 2. The configuration example shown in FIG. 11 is different from the configuration example shown in FIG. 8 in respect that pixels PXR, PXG and PXB are arranged in the first direction X.

In the example shown in FIG. 11, the auxiliary electrode CD has a line shape and extends in the first direction X as seen in plan view. Each of pixels PXR, PXG and PXB arranged in the first direction X partly overlaps the auxiliary electrode CD. In other words, the direction in which pixels PXR, PXG and PXB are arranged is the same as the direction in which the auxiliary electrode CD extends.

The organic EL layer ELR (ELY) of pixel PXR comprises area ELRw overlapping the auxiliary electrode CD, and area ELRn which does not overlap the auxiliary electrode CD. The length (width) of area ELRw in the first direction X is greater than the length (width) of area ELRn in the first direction X.

Similarly, the organic EL layer ELG (ELY) of pixel PXG comprises area ELGw overlapping the auxiliary electrode CD, and area ELGn which does not overlap the auxiliary electrode CD. The length (width) of area ELGw in the first direction X is greater than the length (width) of area ELGn in the first direction X.

The length in which an end portion of the organic EL layer ELY (ELR, ELG, ELB) overlaps the auxiliary electrode CD is only the length of the auxiliary electrode CD in the first direction X. As described above, when an end portion of the organic EL layer ELY overlaps the auxiliary electrode CD, leak current is generated. By decreasing the length of the overlapping portion, leak current can be suppressed.

The organic EL layer ELB (ELY) of pixel PXB comprises area ELBw overlapping the auxiliary electrode CD, and area ELBn which does not overlap the auxiliary electrode CD. The length (width) of area ELBw in the first direction X is greater than the length (width) of area ELBn in the first direction X.

Areas ELRw and ELGw are provided so as to be adjacent to each other. Areas ELGw and ELBw are provided so as to be adjacent to each other. Areas ELBw and ELRw are provided so as to be adjacent to each other. These areas may be provided across an interval or may be provided such that their end portions overlap each other.

The length of area PXBw in the first direction X is greater than that of each of areas PXRw and PXGw in the first direction X. The length of area PXGw in the first direction X is greater than that of area PXRw in the first direction X. In other words, the lengths of areas PXRw and PXGw in the first direction X are increased in this order. The lengths of areas PXRn, PXGn and PXBn in the first direction X are increased in this order.

The lengths of the bottom portion OPb of the opening OP, the common electrode CE and the upper portion OPu of the opening OP in the first direction X are increased in the order of pixels PXR, PXG and PXB.

In the pixels PX (PXR, PXG and PXB) shown in FIG. 11, the area in which the pixel electrode PE overlaps the organic EL layer ELY is spaced apart from the area in which the organic EL layer ELY overlaps the auxiliary electrode CD. The area around the portion in which the pixel electrode PE overlaps the organic EL layer ELY is a light emission area. As described above, when an end portion of the organic EL layer ELY overlaps the auxiliary electrode CD, leak current is generated. As the light emission area is spaced apart from the portion in which leak current is generated, the effect of the leak current can be suppressed.

In the display device DSP shown in FIG. 11, the configuration in which the auxiliary electrode CD extends in the first direction X is explained. However, the configuration is not limited to this configuration example. The auxiliary electrode CD may extend in the second direction Y in a manner similar to that of FIG. 9. The auxiliary electrode CD may extend in both the first direction X and the second direction Y in a manner similar to that of FIG. 10. In this case, the auxiliary electrode CD is formed in a grating shape.

In this configuration example, effects similar to those of embodiment 2 can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a plurality of pixels comprising a first pixel which emits red light, a second pixel which emits green light and a third pixel which emits blue light;
a pixel electrode provided in each of the pixels;
a bank provided between the adjacent pixel electrodes;
an organic EL layer provided on the pixel electrode and provided in an opening of the bank;
a common electrode provided over the first to third pixels; and
an auxiliary electrode provided in at least one of the first to third pixels so as to overlap the common electrode and the organic EL layer.

2. The display device according to claim 1, wherein
the auxiliary electrode is provided so as to overlap the organic EL layer of the first pixel and the common electrode.

3. The display device according to claim 1, wherein
the common electrode is provided between the auxiliary electrode and the organic EL layer.

4. The display device according to claim 1, wherein
the auxiliary electrode is provided between the common electrode and the organic EL layer.

5. A display device comprising:
a plurality of pixels comprising a first pixel which emits red light, a second pixel which emits green light and a third pixel which emits blue light;
a pixel electrode provided in each of the pixels;
a bank provided between the adjacent pixel electrodes;
an organic EL layer provided on the pixel electrode and provided in an opening of the bank;
a common electrode provided in each of the pixels; and
an auxiliary electrode having a line shape and overlapping part of the common electrode.

6. The display device according to claim 5, wherein
the auxiliary electrode comprises first and second auxiliary electrodes parallel to each other,
the first auxiliary electrode overlaps the common electrode of the first pixel and the common electrode of the third pixel, and
the second auxiliary electrode overlaps the common electrode of the second pixel.

7. The display device according to claim 5, wherein
the auxiliary electrode overlaps an end portion of each of the common electrode of the first pixel, the common electrode of the second pixel and the common electrode of the third pixel.

8. The display device according to claim 5, wherein
the auxiliary electrode has a grating shape, and comprises a first area extending in a first direction, a second area extending in a second direction intersecting with the first direction, and a third area in which the first area and the second area intersect each other, and
each of the first to third pixels overlaps at least a single first area and a single second area.

9. The display device according to claim 5, wherein
the first pixel, the second pixel and the third pixel are arranged in a first direction, and
the auxiliary electrode has a line shape and extends in the first direction.

10. The display device according to claim 5, wherein
a thickness of the common electrode is less than a thickness of the auxiliary electrode.
